(19) United States
(12) Patent Application Publication
(10) Pub. No.: US 2008/0043436 A1
(43) Pub. Date: Feb. 21, 2008

(54) THERMAL MODULE

(75) Inventors: JUI-WEN HUNG, Tu-Cheng (TW); CHING-BAI HWANG, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Tu-Cheng (TW)

(21) Appl. No.: 11/309,552

(22) Filed: Aug. 21, 2006

(51) Int. Cl. H05K 7/20

(52) U.S. Cl. 361/700

(57) ABSTRACT

A thermal module (10) includes a chassis (11) of an enclosure of an electronic device, a fin assembly (13) and a centrifugal blower (14) for producing an airflow flowing through the fin assembly. The centrifugal blower includes a housing (141), and the housing is integrally formed with the chassis as a monolithic piece. A U-shaped heat pipe (16) extends through the housing and has a condensing section (161) thermally connecting with the fin assembly and an evaporating section (162) attached to a heat spreader (12) for thermally connecting with a heat generating electronic component.

### FIELD OF THE INVENTION

The present invention relates generally to a thermal module, and more particularly to a thermal module for dissipating heat generated by heat generating electronic components enclosed in a system enclosure, wherein the thermal module has a centrifugal blower integrally formed with the enclosure.

### DESCRIPTION OF RELATED ART

It is well known that heat is produced by electronic components such as integrated circuit chips during normal operation. If this heat is not quickly removed, these electronic components may overheat. Therefore, thermal modules are often used to cool these electronic components.

As an example, a thermal module in accordance with related art generally includes a fin assembly having a plurality of fins, a fan for creating an airflow through the fin assembly, and a heat pipe having an evaporating section which is kept in thermal contact with a heat generating electronic component such as a central processing unit (CPU) of a computer, and a condensing section to which the fin assembly is attached. The heat pipe transfers heat from the heat generating electronic component which is thermally connected with the evaporating section thereof, to the fin assembly which is thermally attached to the condensing section of the heat pipe. The heat is then dissipated into ambient atmosphere via the airflow flowing through the fin assembly.

Typically, the heat generating electronic component is enclosed in a system enclosure such as a computer enclosure, and most individual parts of the thermal module are separately mounted to the enclosure via fasteners such as spring clamps or screws. For example, screws are generally required to mount the fan of the thermal module to the enclosure. Thus, it is a relatively awkward process to assemble the thermal module to the enclosure. Furthermore, in addition to the mold required to form the enclosure, an additional mold is necessary in order to produce the fan of the thermal module; thus increasing the cost of the thermal module.

Therefore, it is desirable to provide a thermal module which can overcome the above-mentioned disadvantages.

### SUMMARY OF THE INVENTION

The present invention relates to a thermal module for dissipating heat generated by a heat generating electronic component. According to a preferred embodiment of the present invention, the thermal module includes a chassis of an enclosure of an electronic device, a fin assembly disposed in the chassis and a centrifugal blower for producing an airflow flowing through the fin assembly. The centrifugal blower includes a housing, and the housing is formed integrally with the chassis of the enclosure as a single piece.

Other advantages and novel features of the present invention will become more apparent from the following detailed description of preferred embodiment when taken in conjunction with the accompanying drawings, in which:

### BRIEF DESCRIPTION OF THE DRAWINGS

Many aspects of the present thermal module can be better understood with reference to the following drawings. The components in the drawings are not necessarily drawn to scale, the emphasis instead being placed upon clearly illustrating the principles of the present thermal module. Moreover, in the drawings, like reference numerals designate corresponding parts throughout the several views.

FIG. 1 is an exploded, isometric view of a thermal module in accordance with a preferred embodiment of the present invention; and

FIG. 2 is an assembled, isometric view of the thermal module of FIG. 1.

### DETAILED DESCRIPTION OF THE INVENTION

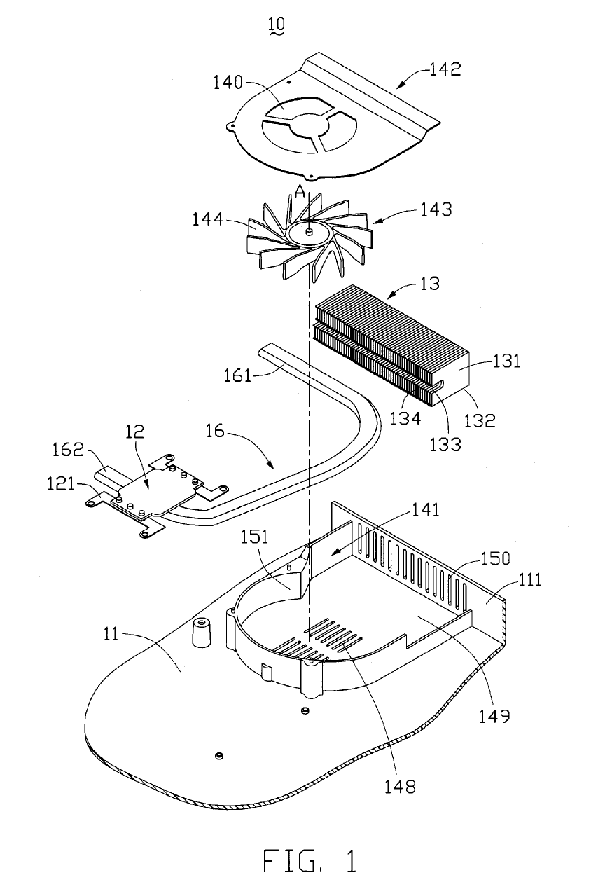

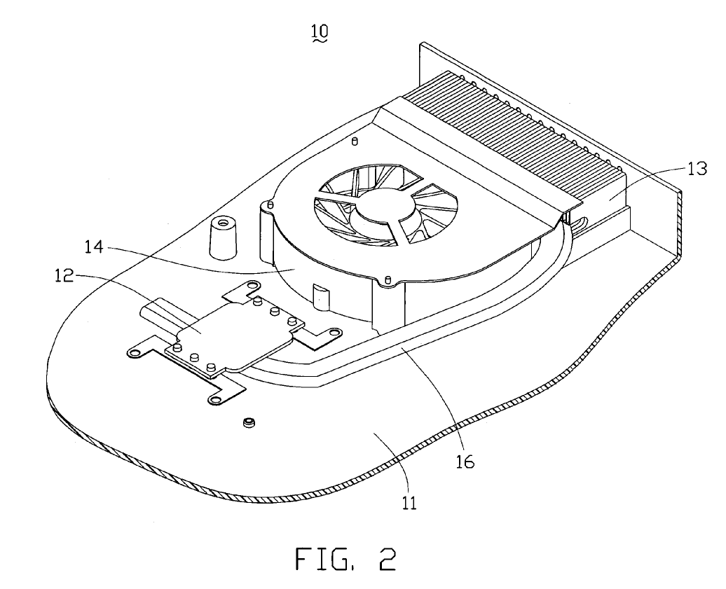

Referring to FIGS. 1-2, a thermal module 10 according to a preferred embodiment of the present invention is shown. The thermal module 10 includes a chassis 111 of a computer enclosure, a heat spreader 12, a fin assembly 13, a centrifugal blower 14 (see FIG. 2) and a U-shaped heat pipe 16. The heat spreader 12 has good heat conduction, and thermally connects with a heat generating electronic component (not shown) in the chassis 11. The heat pipe 16 has one end thermally contacting with the heat generating electronic component via the heat spreader 12, and another end attached to the fin assembly 13. The centrifugal blower 14 produces an airflow flowing through the fin assembly 13 to take heat away therefrom.

In this embodiment, the chassis 111 is a part of a computer enclosure such as a notebook computer enclosure or a desktop computer enclosure. Alternatively, the chassis 11 also may be an enclosure of an electronic device, such as a projector, with the heat generating electronic component enclosed therein. A straight sidewall 111 is formed on one side of the chassis 11. The heat spreader 12 has four spring members 121 formed at four corners thereof, respectively. The spring members 121 are integrally formed with the heat spreader 12 or secured to the heat spreader 12 by means of rivets or screws. The heat spreader 12 is mounted to the heat generating electronic component via screws (not shown) extending through the spring members 121, for absorbing heat generated by the heat generating electronic component.

The heat pipe 16 is flattened so as to increase the surface area contacting with the heat spreader 12 and the fin assembly 13. The heat pipe 16 includes an evaporating section 162 for being soldered to the heat spreader 12, and a condensing section 161 to which the fin assembly 13 is attached.

The fin assembly 13 includes a plurality of stacked parallel fins 131. A plurality of air passages 134 are formed between two adjacent fins 131 for guiding the airflow produced by the centrifugal blower 14 to pass therethrough. The fin assembly 13 includes a bottom surface 132 at a bottom thereof, and a C-shaped receiving channel 133 at a lateral side thereof for receiving the condensing section 161 of the heat pipe 16 therein. A layer of thermal interface material (not shown), such as thermal grease, is arranged at the contacting surfaces between the fin assembly 13 and the condensing section 161 of the heat pipe 16, and the contacting surfaces between the heat spreader 12 and the evaporating section 162 of the heat pipe 16, so as to improve the heat conduction efficiency of the thermal module 10.

The centrifugal blower 14 includes a housing 141, a cover 142 attached to the housing 141 with an inner space (not labeled) formed therebetween, a stator (not shown) accommodated in the inner space, and a rotor 143 rotatably disposed around the stator.

The cover 142 defines a plurality of through holes therein functioning as a first air inlet 140 for the centrifugal blower 14. The housing 141 is shaped as a U-shaped sidewall, and is integrally formed with the chassis 11 as a monolithic piece. The chassis 11 and the housing 141 are made of a highly thermally conductive material such as copper, zinc, aluminum, magnesium or their alloys, and they are manufactured by means of die-casting. Alternatively, the chassis 111 and the housing 141 are made of plastic, and the housing 141 can be integrally formed with the chassis 111 by means of plastic injection molding.

The rotor 143 of the centrifugal blower 14 includes a plurality of blades 144. The chassis 111 is perpendicular to a rotation axis A of the rotor 143, and defines a plurality of rectangular through holes at a position which corresponds to the rotor 143, for functioning as a second air inlet 148 for the centrifugal blower 14. The housing 141 defines an air outlet 149 facing the sidewall 111 of the chassis 11. The fin assembly 13 is disposed at the air outlet 149 of the centrifugal blower 14, with the bottom surface 132 thereof intimately contacting with the chassis 11. A plurality of elongated vents 150, which are parallel to the air passages 134 of the fin assembly 13, are formed on the sidewall 111 of the chassis 111 and communicate with the air outlet 149 of the centrifugal blower 14. The vents 150 are spaced a distance from each other and communicate with the air passages 134 of the fin assembly 13, for reducing airflow resistance to air passing through the air passages 134. The housing 141 protrudes a triangle-shaped tongue 151 pointing towards the blades 144 of the rotor 143. The tongue 151 is disposed closer to the blades 144 of the rotor 143 than other portions of the housing 141 to thereby increase an air pressure of the airflow when the airflow flows past the tongue 151.

During operation of the centrifugal blower 14, ambient cool air is inhaled into the housing 141 from the first and second air inlets 140, 148 of the centrifugal blower 14, and then flows towards the air outlet 149 and through the fin assembly 13. The airflow then passes successively through the air passages 134 of the fin assembly 13 and the vents 150 of the sidewall 111, thus taking heat away from the fin assembly 13 into the ambient atmosphere.

In the present thermal module 10, the housing 141 of the centrifugal blower 14 is integrally formed with the chassis 11. During assembly, the condensing section 161 and the evaporating section 162 of the heat pipe 16 engage with the fin assembly 13 and the heat spreader 12, respectively. The heat spreader 12 is secured to the heat generating electronic component. The fin assembly 13 is disposed at the air outlet 149 of the centrifugal blower 14, with the air passages 134 of the fin assembly 13 communicating with the vents 150 of the sidewall 111. The rotor 143 of the centrifugal blower 14 is secured to the cover 142, and accommodated in the inner space formed between the cover 142 and the housing 141. The heat pipe 16 extends through the housing 141 to connect the fin assembly 13 and the heat spreader 12 together.

In the present thermal module 10, since the housing 141 of the centrifugal blower 14 is integrally formed with the chassis 11, there is no need to use additional fasteners such as spring clamps or screws to secure the centrifugal blower 14 to the chassis 11. Thus, the thermal module 10 can be assembled more easily. Furthermore, it is not necessary to provide individual molds for both the centrifugal blower 14 and the chassis 11, and as a result the cost of the present thermal module 10 is reduced. Moreover, the heat pipe 16 transfers the heat generated by the heat generating electronic component from the heat spreader 12 thermally connecting with the heat generating electronic component to the fin assembly 13. When the chassis 11 and the housing 141 are formed integrally from a highly thermally conductive material, the heat conveyed to the fin assembly 13 can be further transferred to the chassis 11 and the housing 141. In this way, a part of the heat is dissipated into the ambient atmosphere via the fin assembly 13, and another part of the heat is dissipated via the chassis 11. Accordingly, the heat dissipation surface area is increased and the heat dissipation efficiency of the thermal module 10 is improved.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A thermal module comprising:
a chassis of an enclosure of an electronic device;
a fin assembly disposed in the chassis; and
a centrifugal blower including a housing and producing an airflow flowing through the fin assembly, wherein
the housing is integrally formed with the chassis as a monolithic piece.

2. The thermal module of claim 1, wherein the chassis is made of copper, zinc, aluminum, magnesium or alloys thereof.

3. The thermal module of claim 1, wherein the chassis is made of plastic.

4. The thermal module of claim 1, wherein the centrifugal blower further comprises a cover and a rotor accommodated in a space formed between the cover and the housing, wherein the housing is shaped as a sidewall.

5. The thermal module of claim 4, wherein the chassis defines an air inlet at a position which corresponds to the rotor of centrifugal blower.

6. The thermal module of claim 1, wherein the chassis further comprises a sidewall, and the sidewall defines at least a vent, wherein the housing of the centrifugal blower defines an air outlet facing said at least vent, and the fin assembly is disposed at the air outlet of the centrifugal blower.

7. The thermal module of claim 6, wherein the fin assembly includes a plurality of parallel fins stacked together, and a plurality of air passages are formed between every two adjacent fins, wherein the air passages communicate the at least a vent of the sidewall.

8. The thermal module of claim 1, wherein a triangle-shaped tongue pointing towards the rotor protrudes from the housing.

9. The thermal module of claim 1, further comprising a heat pipe, wherein one end of the heat pipe thermally contacts with a heat generating electronic component mounted in the enclosure, and the other end thereof is attached to the fin assembly.

10. A thermal module, comprising:
a heat spreader adapted for thermally contacting with a heat generating electronic component;
a fan housing defining an air inlet and an air outlet perpendicular to the air inlet;
a fin assembly disposed at the air outlet for dissipating heat generated by the heat generating electronic component; and
a heat pipe thermally connecting the heat spreader with the fin assembly; wherein the heat spreader, the fan housing, the fin assembly and the heat pipe are received in a chassis of an enclosure of an electronic device which encloses the heat generating electronic component therein, and the fan housing is an integrally formed part of the chassis of the enclosure.

11. The thermal module of claim 10, wherein the heat spreader has a plurality of spring members formed at corners thereof for securing the heat spreader in the chassis of the enclosure.

12. The thermal module of claim 10, wherein the heat pipe is flattened and has an evaporating section attached to the heat spreader and a condensing section received in a C-shaped slot defined at a lateral side of the fin assembly.

13. The thermal module of claim 10, wherein the chassis of the enclosure and the fan housing are integrally formed from a metallic material and the fin assembly has a bottom surface directly attached to the chassis of the enclosure.

14. The thermal module of claim 10, wherein the chassis of the enclosure has a sidewall located near to the air outlet of the fan housing and the sidewall defines a plurality of elongated vents communicating with the air outlet of the fan housing.

15. An electronic device comprising:
a chassis;
a U-shaped wall on the chassis and cooperating with the chassis to define a space within the U-shaped wall and above the chassis;
a rotor rotatably received in the space for generating an airflow;
a fin assembly received in the space wherein the airflow flowing through the fin assembly; and
a heat pipe having a condensing section thermally connecting with the fin assembly and an evaporating section for thermally connecting with a heat generating electronic component of the electronic device.

16. The electronic device of claim 15, wherein the U-shaped wall is integrally formed with the chassis as a single piece by one of following methods: die casting of metallic material and injection molding of plastic material.

17. The electronic device of claim 16, wherein the heat pipe is U-shaped and extends through the U-shaped wall.

18. The electronic device of claim 17, wherein the U-shaped wall has a tongue pointing towards blades of the rotor for increasing air pressure of the airflow.

19. The electronic device of claim 15 further comprising a heat spreader attached to the evaporating section of the heat pipe for thermally connecting with the heat generating electronic component.

20. The electronic device of claim 15 further comprising a straight sidewall, wherein the fin assembly is located between the rotor and the straight sidewall, the straight sidewall defining a plurality of vents, the airflow flowing through the fin assembly and then the vents to leave the electronic device.
